(19) United States
(12) Patent Application Publication
(10) Pub. No.: US 2026/0275511 A1
(43) Pub. Date: Sep. 17, 2026

(54) SUBSTRATE PROCESSING APPARATUS AND SUBSTRATE PROCESSING METHOD

(71) Applicant: WONIK IPS CO., LTD., Pyeongtaek-si Gyeonggi-do (KR)

(72) Inventors: Hyun Muk JUNG, Pyeongtaek-si Gyeonggi-do (KR); Jin KANG, Pyeongtaek-si Gyeonggi-do (KR)

(73) Assignee: WONIK IPS CO., LTD., Pyeongtaek-si Gyeonggi-do (KR)

(21) Appl. No.: 18/873,026

(22) PCT Filed: Aug. 3, 2023
(86) PCT No.: PCT/KR2023/011387

§ 371 Date: Dec. 9, 2024

(30) Foreign Application Priority Data
Jan. 4, 2023 (KR) 10-2023-0001373

(51) Int. Cl. C23C 16/44; B01D 46/00; B01D 46/44; B01D 46/46; C23C 16/458; H10P 72/00

(52) U.S. Cl. CPC C23C 16/4401; B01D 46/0041; B01D 46/442; B01D 46/46; C23C 16/4583; H10P 72/0402; B01D 2279/51

(57) ABSTRACT

Disclosed is an apparatus for processing a substrate. According to an embodiment of the present disclosure, a substrate-processing apparatus is provided. The substrate-processing apparatus includes a reaction tube in which substrate processing is performed, a boat which is introduced into and taken out from the reaction tube through a boat-lifting unit and on which multiple substrates are seated in a vertical direction, a substrate-loading part in which a loading area is formed, the multiple substrates being loaded into or unloaded from the boat in the loading area through a substrate transfer robot, an external air inlet for controlling the amount of external air flowing into the loading area, a gas control device for controlling the injection amount of inert gas, a particle-measuring sensor for measuring particle information of the loading area and a controller for controlling one or more of the external air inlet and the gas control device.

### TECHNICAL FIELD

The present disclosure relates to a substrate-processing apparatus and a substrate-processing method, and more particularly an apparatus for processing a substrate and a method thereof.

### RELATED ART

In general, semiconductor devices and display devices are manufactured through various processes such as thin-film deposition and etching on a substrate, and a batch-type deposition system is used as a single system for processing a substrate.

A batch-type deposition system can be configured such that Front Opening Unified Pods (FOUPs) that accommodate multiple substrates are brought into its interior through a load port and stored in shelves (stockers). These shelves are formed in a plurality of vertical stacks on a shelf frame, and the FOUPs stored on the shelves can be brought into contact with a Front-opening Interface Mechanical Standard (FIMS) door part by a transfer robot moving along a vertically extended transfer robot rail.

Next, after the FIMS is pressed against the door part, the substrate transfer robot can receive the multiple substrates using a transfer fork in the FOUPs with one side open, and the substrate transfer robot can move down to stack the multiple substrates on a boat.

In this batch-type deposition system, multiple substrates can loaded into a substrate-loading part, a boat can be formed inside, and the multiple substrates can be stacked on the boat in a loading area inside the substrate-loading part.

Here, the loading area is an area where multiple substrates are exposed, and if particles occur within the loading area, it can have a significant impact on the wafer quality. However, since particles in the loading area cannot be detected in real-time and a user cannot check the particles, it is impossible to respond to wafer quality problems due to unexpected particle occurrence.

### DISCLOSURE

### Summary

In accordance with an aspect of the present disclosure, the above and other objects can be accomplished by the provision of a substrate-processing apparatus, including: a reaction tube which has an opening at a bottom thereof and in which substrate processing is performed; a boat which is introduced into and taken out from the reaction tube through a boat-lifting unit and on which multiple substrates are seated in a vertical direction; a substrate-loading part which is placed under the reaction tube and in which a loading area is formed, the multiple substrates being loaded and unloaded into the boat in the loading area through a substrate transfer robot; an external air inlet which is formed on one side of the substrate-loading part, is connected to the loading area such that external air is introduced into the loading area, and controls an amount of the introduced external air; a gas control device which controls an injection amount of inert gas supplied into the loading area; a particle-measuring sensor which measures particle information of the loading area; and a controller which controls one or more of the external air inlet and the gas control device according to the particle information received from the particle-measuring sensor to reduce particles in the loading area.

In accordance with another aspect of the present disclosure, there is provided a substrate-processing method. The substrate-processing method includes a process processing step in which a boat where multiple substrates are seated in a vertical direction through a boat-lifting unit is introduced into or taken out from an opening formed at a bottom of a reaction tube, in which substrate processing is performed, to process the multiple substrates; a particle measurement step of measuring particle information of a loading area in a substrate-loading part placed under the reaction tube before or after the process processing step, the multiple substrates being loaded and unloaded into the boat in the loading area; and a control step of controlling one or more of an external air inlet for controlling an amount of external air flowing into the loading area; and a gas control device for controlling an injection amount of inert gas supplied into the loading area, so as to reduce particles in the loading area according to the particle information measured in the particle measurement step.

### BRIEF DESCRIPTION OF DRAWINGS

FIG. 1 illustrates a substrate-processing apparatus according to an embodiment of the present disclosure.

FIG. 2 illustrates a flowchart for explaining the operation of the substrate-processing apparatus.

FIG. 3 illustrates the operations of a fan filter unit and gas control device according to the size of particles measured by the substrate-processing apparatus of the present disclosure.

FIG. 4 illustrates a flowchart for explaining a substrate-processing method according to an embodiment of the present disclosure.

FIGS. 5a and 5b are graphs illustrating changes in the amount of particles according to the operations of an external air inlet and gas control device of the substrate-processing apparatus according to an embodiment of the present disclosure.

### DETAILED DESCRIPTION

Hereinafter, one or more preferred embodiments of the present disclosure will be described in detail with reference to the accompanying drawings.

Embodiments of the present disclosure are provided to more completely explain the present disclosure to those skilled in the art, and the following embodiments may be modified in many different forms, but the scope of the present disclosure is not limited to the following embodiments. Rather, the embodiments are provided to make the disclosure thorough and complete and to fully convey the technical idea of the disclosure to those skilled in the art. In the drawings, the thicknesses and sizes of layers may be exaggerated for convenience and clarity of explanation.

Embodiments of the disclosure are described herein with reference to drawings that schematically illustrate idealized embodiments of the disclosure. As such, variations from the shapes of the illustrations as a result, for example, of manufacturing techniques and/or tolerances, are to be expected. Thus, embodiments of the disclosure should not be construed as limited to the particular shapes of regions illustrated herein but are to include deviations in shapes that result, for example, from manufacturing.

Therefore, the present disclosure has been made in view of the above problems, and it is one object of the present disclosure to provide a substrate-processing apparatus for executing a sequence capable of suppressing particles by controlling the weight of a fan of a fan filter unit (FFU) or the airflow of purge gas to remove particles inside a loading area where substrates are loaded, and a substrate-processing method thereof. However, this object is exemplary and the scope of the present disclosure is not limited thereto.

In accordance with some embodiment of the present disclosure as described above, real-time monitoring of particles by size within a loading area is possible, and when particles are generated, the particles can be reduced through a suppression control algorithm.

In addition, depending on particles caused by physical detachment and particles caused by chemical reaction, the generation of additional particles can be prevented by selectively operating external air control or the injection amount control of inert gas to control it differently according to the particle generation cause, thereby improving the processing quality of substrates. Naturally, these effects do not limit the scope of the present disclosure.

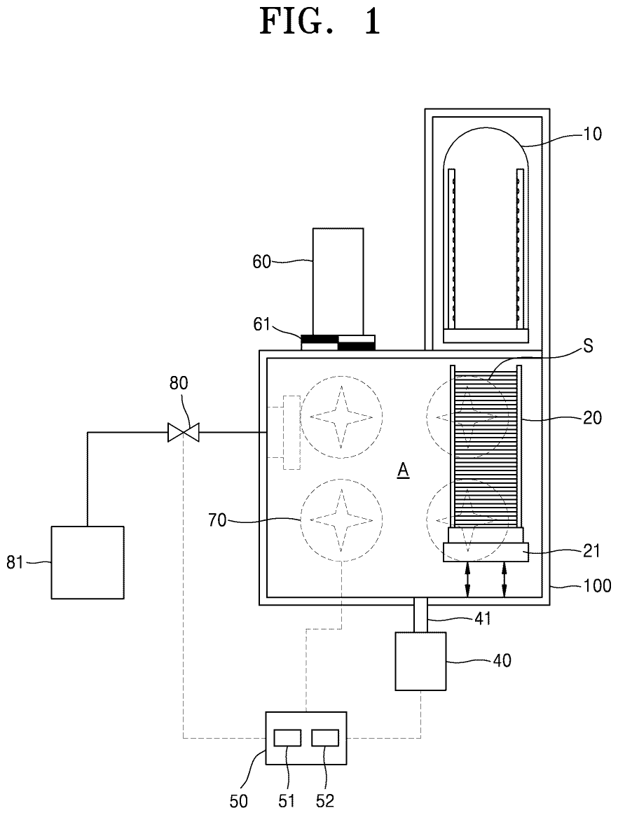

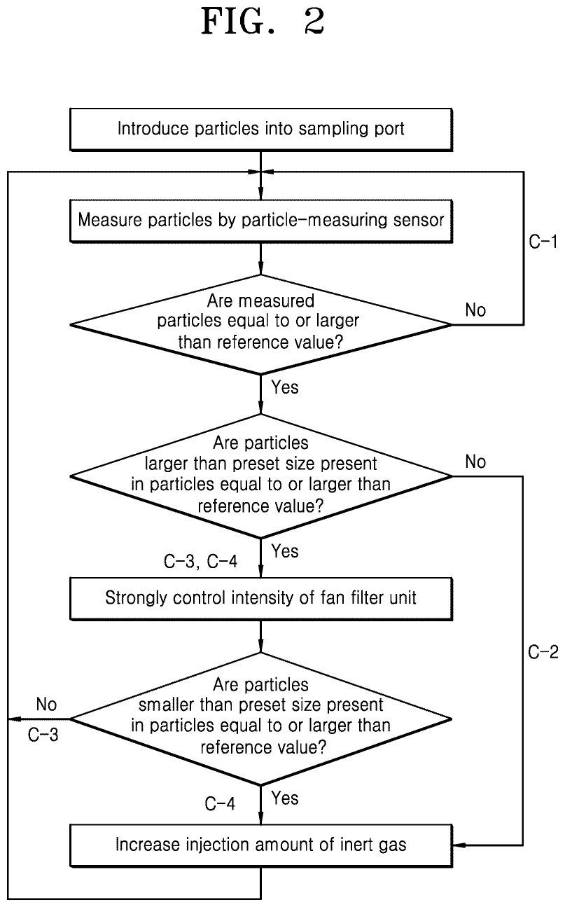

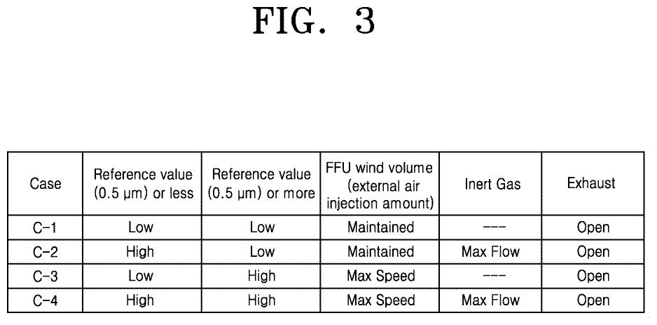

FIG. 1 illustrates a substrate-processing apparatus according to an embodiment of the present disclosure, FIG. 2 illustrates a flowchart for explaining the operation of the substrate-processing apparatus of FIG. 1, and FIG. 3 illustrates the operations of a fan filter unit and gas control device 80 according to the size of particles measured by the substrate-processing apparatus of the present disclosure.

First, the substrate-processing apparatus according to an embodiment of the present disclosure may largely include a reaction tube 10, a boat 20, an external air inlet 70, a gas control device 80, a particle-measuring sensor 40 and a controller 50.

As shown in FIG. 1, the reaction tube 10 has an opening formed at its bottom and may include a process tube that accommodates the boat 20 such that multiple substrates S can be processed, and a gas supply part necessary for a deposition process, or components such as a gas discharge part may be installed inside the reaction tube 10.

Specifically, the reaction tube 10 may be composed of an inner tube and an outer tube and may be made of a heat-resistant material such as quartz. An exhaust port (not shown) may be formed to exhaust the inside of the reaction tube 10, and the exhaust port may be connected to a pump (not shown) with pumping capability.

A manifold having gas supply pipes (not shown) installed for supplying gas to the inside of the reaction tube 10 may be formed on one side of the reaction tube 10, and the gas supply pipes may be connected to a gas nozzle (not shown) extending upward from the inside of the reaction tube 10.

The boat 20 may be introduced into and taken out from the reaction tube 10 by a boat-lifting unit 21, multiple substrates S picked up through a substrate transfer robot may be placed in a vertical direction, and the boat 20 may be lifted and lowered in a state where the multiple substrates S are stacked thereinside. Here, when the boat 20 is lifted, a support part may be sealedly connected to the reaction tube 10.

When the multiple substrates S are loaded into the boat 20, the boat 20 may be lifted and placed in the reaction tube 10. Process gases may be sprayed from the reaction tube 10 to deposit a thin film on the multiple substrates S.

As shown in FIG. 1, the external air inlet 70 may be formed on at least one side of a substrate-loading part 100 and may include a blower fan and a filter.

The external air inlet 70 is a device for controlling the amount of external air introduced from an inlet pipe.

For example, the external air inlet 70 may include a plurality of blower fans formed on the side of a loading area A, and external air may be introduced from outside the loading area A into the loading area A through the rotation of the blower fans. Here, the amount of external air introduced may vary depending on the rotational strength of the blower fans.

The external air inlet 70 may include a filter that filters contaminants contained in external air introduced from the outside before the external air is introduced into the loading area A through the blower fans. The filter may be coupled to each of the plural blower fans, or may be formed to surround at least one side of a frame to which the plural blower fans are coupled.

For example, the external air inlet 70 may be formed on one side of the loading area A and may include a fan filter unit that controls the amount of external air flowing from the external air inlet 70.

The external air inlet 70 may be formed on one side of the substrate-loading part 100 and may introduce external air into the loading area A through an inlet pipe connected to the loading area A.

The inlet pipe may be formed on the side of the substrate-loading part 100 and at the rear of the blower fans, or may be formed at the upper part of the rear of the blower fans so that the external air flowing into the inlet pipe flows from the top to the bottom.

In addition, to exhaust the internal gas of the loading area A to the outside, an exhaust pipe 60 and a blocking valve 61 may be formed in at least a part of the substrate-loading part 100. Here, the exhaust pipe 60 may exhaust in all directions, such as a slit damper formed on the side, a T/R damper formed on the bottom, and a L/A exhaust pipe formed on the top.

The exhaust pipe 60 may be formed on all sides of the substrate-loading part 100 and may induce the flow in the loading area A to change according to the exhaust of air or gas within the loading area A, thereby inducing the discharge of particles remaining in the loading area A.

As shown in FIG. 1, the gas control device 80 may control the injection amount of inert gas supplied into the loading area A.

Specifically, the gas control device 80 may be formed on at least a portion of a flow line that connects a gas supply part 81, which is formed on the outside of the loading area A to supply the inert gas, to the loading area A.

The gas control device 80 is a gas control valve that blocks the flow of the inert gas or blocks the backflow of gas or external air. For example, the gas control device 80 is a mass flow controller (MFC) that can accurately and quickly control the flow rate of the inert gas supplied. The gas control device 80 may be controlled by the controller 50 described below.

The inert gas may include nitrogen gas and argon gas, and in addition, may include gases whose gas molecular bonds are strong and not easily broken or whose atoms themselves are stable and do not undergo chemical reactions.

As shown in FIG. 1, the particle-measuring sensor 40 may include a device for measuring particle information of the loading area A inside the substrate-loading part 100 where the reaction tube 10 and the boat 20 are formed.

Specifically, the particle-measuring sensor 40 may measure the size and amount of particles present in the loading area A by sampling a portion of the gas or air of the loading area A and measuring particle information included in the sampling. Here, the particle information may include the size and amount of particles included in the sample.

For example, the particle-measuring sensor 40 may be formed inside the substrate-loading part 100, a portion of the gas or air of the loading area A may flow into the particle-measuring sensor 40, and the size and amount of particles contained in the introduced gas or air may be measured by the particle-measuring sensor 40. Preferably, the particle-measuring sensor 40 may be formed on one side of the substrate-loading part 100 and sample gas or air flowing into a sampling port 41 connected to the loading area A, thereby measuring the size and amount of particles contained within the sample and, accordingly, measuring particle information existing in the loading area A.

The particle-measuring sensor 40 may be connected to the controller 50 by wire or wirelessly, record and store the particle information, and transmit the particle information to the controller 50.

The sampling port 41 may be located on the bottom of the loading area A such as the FIMS, the boat 20 or the transfer robot, and may be formed as one or more capturing ports for capturing particles falling downward.

The controller 50 may control at least one of the air atmosphere and inert gas atmosphere inside the loading area A according to the particle information received from the particle-measuring sensor 40 so as to reduce the particles in the loading area A.

Specifically, the controller 50 may control the air volume output of the fan filter unit, which controls the amount of external air flowing into the loading area A, from 0% to 100% according to the particle information measured by the particle-measuring sensor 40, may control the flow rate of the inert gas injected from the gas control device 80, which controls the injection amount of inert gas in the loading area, from 0 slm to 2,000 slm, and may selectively control the fan filter unit and the gas control device 80.

The controller 50 may include a particle amount determination part 51 that compares the amount of particles measured by the particle-measuring sensor 40 with a preset reference value; and a particle size determination part 52 that determines the size of particles measured by the particle-measuring sensor 40 when the amount of the particles are measured to be equal to or larger than the reference value.

Specifically, when the amount of particles larger than the preset size is measured to be equal to or larger than the reference value by the particle-measuring sensor 40, the controller 50 may control the intensity of the fan filter unit so that the amount of external air flowing into the loading area A increases.

For example, when the particles, measured to be larger than the reference value by the particle amount determination part 51, among the particles detected by the particle-measuring sensor 40 is determined to be equal to or larger than the size that is set by the particle size determination part 52, the controller 50 may control the intensity of the fan filter unit to be operated more strongly than the maintained state.

Here, as the operation of the fan filter unit is strongly controlled, the exhaust pipes including the slit damper, T/R damper, L/A, etc. described above may be opened to lower the particle concentration in the loading area A.

Specifically, the case where particles larger than the set size occur in an amount equal to or larger than the reference value is generally because physical detachment of a material surface, such as peeling or cracking of the surface, has occurred, or dust or contaminants have been introduced from the outside. Therefore, the controller 50 may control the fan filter unit to operate strongly to introduce a large amount of external air and, accordingly, discharge foreign substances floating in the loading area A to the outside.

In addition, the controller 50 may control the gas control device 80 that controls an injection amount into the loading area A to increase the injection amount of inert gas when the amount of particles, smaller than the preset size, measured by the particle-measuring sensor 40 is equal to or larger than the reference value.

For example, among particles detected by the particle-measuring sensor 40, when particles measured to be equal to or larger than the reference value by the particle amount determination part 51 are determined to be smaller than a size set by the particle size determination part 52, the controller 50 may control the gas control device 80 to increase the injection amount of the inert gas flowing into the loading area A.

Here, the operation of the fan filter unit may be maintained at the existing intensity so that the inert gas can flow into the loading area A, and the exhaust pipes including the Slit Damper, T/R Damper, L/A, etc. described above may be opened to reduce the particle concentration of the loading area A.

Specifically, the case where particles, e.g., particles having a size of about 0.1 μm, smaller than the set size are generated in an amount equal to or larger than the reference value is generally because elements or ions such as fume, e.g., H+, OH—, Cn, emitted from the substrate-loading part 100 combine with oxygen elements to form reactants, so that the controller 50 can control the injection of a large amount of inert gas to suppress the formation of particles by chemical reaction, thereby preventing the generation of particles and discharging the generated particles.

In addition, when responding by injecting a large amount of external air, the controller 50 may control to increase the density of the inert gas, thereby preventing the formation of oxides or carbon compounds.

When particles larger than the preset size are measured to be equal to or larger than the reference value by the particle-measuring sensor 40 and particles smaller than the preset size are measured to be equal to or larger than the reference value, the controller 50 may respectively operate the fan filter unit and the gas control device 80 at predetermined time intervals to alternately increase the amount of external air flowing into the loading area A and the injection amount of inert gas.

That is, when the amount of particles is measured to be equal to or larger than the reference value by the particle amount determination part 51, and the particle size determination part 52 determines that both particles larger than the preset size and particles smaller than the preset size exist, the controller 50 may maximally operate the fan filter unit to exhaust particles due to physical detachment, and may operate the gas control device 80 to increase the injection amount of the inert gas flowing into the loading area A and exhaust particles due to chemical reaction.

Here, the fan filter unit may be operated for a certain time, and then the gas control device 80 may be controlled for a certain time again to perform alternately.

As shown in FIG. 2, particles may be introduced into the sampling port 41 formed on one side of the substrate-loading part 100 and constructed to connect the loading area A and the particle-measuring sensor 40 to each other, by the operation of the substrate-processing apparatus according to the present disclosure.

Next, a portion of gas or air in the loading area A may be sampled and measured by the particle-measuring sensor 40. Here, the particle amount determination part 51 of the controller 50 may determine whether the measured particles are equal to or larger than the reference value, and if they are determined to be less than the reference value, the standard flow rate control state may be continuously maintained. That is, as in case C-1 of FIG. 3, the air volume of a fan filter unit may be maintained at the standard state, the gas control device 80 does not spray, and the exhaust pipe may be controlled to be opened.

Next, particles of the continuously introduced sample may be measured, or particles sampled at a predetermined next cycle, such as a certain time or before and after the process, may be measured.

In addition, when the particles measured by the particle amount determination part 51 of the controller 50 are determined to be equal to or larger than the reference value, the particle size determination part 52 may determine whether particles larger than the preset size exist.

When there are no particles larger than the preset size among the detected particles, i.e., there are particles smaller than or equal to the preset size, the gas control device 80 may increase the injection amount of the inert gas. That is, as in case C-2 of FIG. 3, the wind volume of the fan filter unit may be maintained at a standard state, the injection amount of the gas control device 80 may be maximized, and the exhaust pipe may be controlled to be opened.

When particles larger than the preset size are present in the detected particles, the wind volume of the fan filter unit may be strongly controlled. That is, as in cases C-3 and C-4 of FIG. 3, the wind volume of the fan filter unit may be increased to the maximum speed, and the exhaust pipe may be controlled to be opened.

Here, the particle size determination part 52 of the controller 50 may determine whether there are particles smaller than the preset size.

When particles smaller than the preset size are absent in the detected particles, the wind volume of the fan filter unit may be strongly maintained, and the gas control device 80 may be maintained in the standard flow rate control state without spraying an inert gas. That is, as in case C-3 of FIG. 3, the wind volume of the fan filter unit may be increased to the maximum speed, the gas control device 80 may not spray, and the exhaust pipe may be controlled to be opened.

Next, particles of the continuously introduced sample may be measured, or particles sampled at a predetermined next cycle, such as a certain time or before and after the process, may be measured.

When particles smaller than the preset size are present in the detected particles, the wind volume of the fan filter unit may be strongly maintained, and the gas control device 80 may increase the injection amount of inert gas. As in case C-4 of FIG. 3, the wind volume of the fan filter unit may be increased to the maximum speed, the injection amount of the gas control device 80 may be minimized, and the exhaust pipe may be controlled to be opened.

Next, particles of the continuously introduced sample may be measured, or particles sampled at a predetermined next cycle, such as a certain time or before and after the process, may be measured.

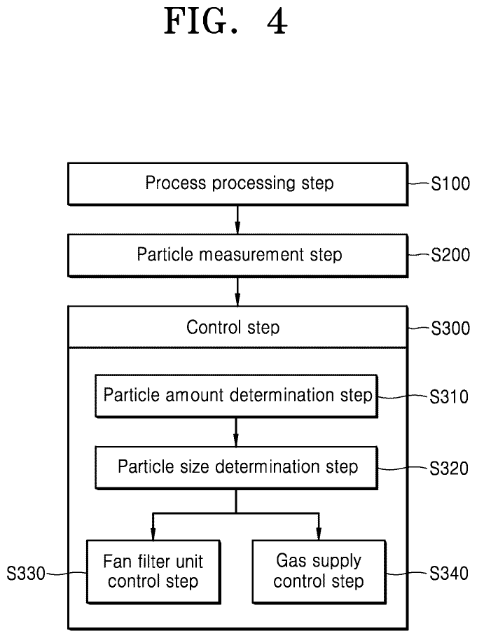

FIG. 4 illustrates a flowchart for explaining a substrate-processing method according to an embodiment of the present disclosure.

The substrate-processing method according to an embodiment of the present disclosure may include a process processing step S100, a particle measurement step S200 and a control step S300.

As shown in FIG. 4, the process processing step S100 is a step in which the boat 20 on which multiple substrates S are placed in a vertical direction through the boat-lifting unit 21 is loaded or unloaded into an opening formed at the bottom of the reaction tube 10 in which substrate processing is performed, thereby processing multiple substrates S.

The process processing step S100 is a step in which multiple substrates S picked up by the substrate transfer robot are lifted and lowered through the boat-lifting unit 21 in a state in which they are placed in a vertical direction of the boat 20 and stacked thereinside, and are then brought into the reaction tube 10 formed as a process tube to process the multiple substrates S.

The process processing step S100 may include a step in which the support part is sealedly connected to the reaction tube 10 when the boat 20 is raised.

The particle measurement step S200 is a step of measuring particle information of the loading area A inside the substrate-loading part 100 where the reaction tube 10 and the boat 20 are formed, using the particle-measuring sensor 40 before or after the process processing step S100.

As shown in FIG. 4, the particle measurement step S200 may be performed before the process processing step S100, and although not shown, may be performed after the process processing step S100 or during the process processing step S100.

The particle measurement step S200 is a step of measuring the size and amount of particles that are formed inside the substrate-loading part 100 and, as a portion of gas or air in the loading area A is introduced into the particle-measuring sensor 40, that are contained in the introduced gas or air.

Preferably, the particle measurement step S200 is a step of sampling gas or air introduced into the sampling port 41 connected to the loading area A and measuring the size and amount of particles contained in the sample to measure particle information existing in the loading area A.

As shown in FIG. 4, the control step S300 is a step of controlling at least one of the atmospheric atmosphere and inert gas atmosphere inside the loading area A by the controller 50 so as to reduce particles in the loading area A according to the particle information measured in the particle measurement step S200, and specifically, it is a step of controlling the external air inlet 70 that controls the amount of external air flowing into the loading area A; and the gas control device 80 that controls the amount of inert gas injected into the loading area.

Specifically, the control step S300 may include a particle amount determination step S310 of comparing the amount of particles measured in the particle measurement step S200 with a preset reference value; and a particle size determination step S320 of determining the size of particles measured in the particle measurement step S200 when the particles are measured to be equal to or larger than a reference value.

The control step S300 may include a fan filter unit control step S330 and a gas supply control step S340.

The fan filter unit control step S330 is a step of controlling the strength of the external air inlet 70 to increase the amount of external air flowing into the loading area A when particles larger than the preset size are measured to be equal to or larger than the reference value in the particle measurement step S200.

For example, when particles, which have been determined to be equal to or larger than the reference value by the particle amount determination step S310, among the particles detected in the particle measurement step S200 are determined to be larger than the size set in the particle size determination step S320, the fan filter unit control step S330 is a step of controlling the intensity of the external air inlet 70, e.g., a fan filter unit, to be driven more strongly than a maintained state.

Here, the fan filter unit control step S330 may further include a step of opening the exhaust pipe including the slit damper, the T/R damper, L/A, etc. described above, as the operation of the fan filter unit is strongly controlled, thereby reducing the particle concentration of the loading area A.

The gas supply control step S340 is a step of controlling the gas control device 80 for adjusting the injection amount of inert gas into the loading area A to increase the injection amount of the inert gas when particles smaller than the preset size are measured to be equal to or larger than the reference value in the particle measurement step S200.

For example, when particles, which have been measured to be equal to or larger than the reference value in the particle amount determination step S310, among the particles detected in the particle measurement step S200 are determined to be smaller than the size set in the particle size determination step S320, the gas supply control step S340 controls the gas control device 80 to increase the injection amount of the inert gas flowing into the loading area A.

Here, the gas supply control step S340 further includes a step of maintaining the operation of the external air inlet 70, e.g., the fan filter unit, at the existing intensity such that the inert gas can be introduced into the loading area A, and opening the exhaust pipes including the Slit Damper, T/R Damper, L/A, etc. described above, and may lower the particle concentration of the loading area A.

In addition, when the particles detected in the particle measurement step S200 include both particles larger than the preset size and particles smaller than the preset size, the gas supply control step S340 and the fan filter unit control step S330 may be alternately performed.

Furthermore, when the detected particles are continuously detected for a certain time in an amount equal to or larger than the reference value, the boat 20 may be taken out to the reaction tube 10, or the inflow of substrates is stopped in the FIMS outside the substrate-loading part 100, and the particles may be continuously controlled so that they are not detected in the loading area A, thereby protecting the multiple substrates S from the particles.

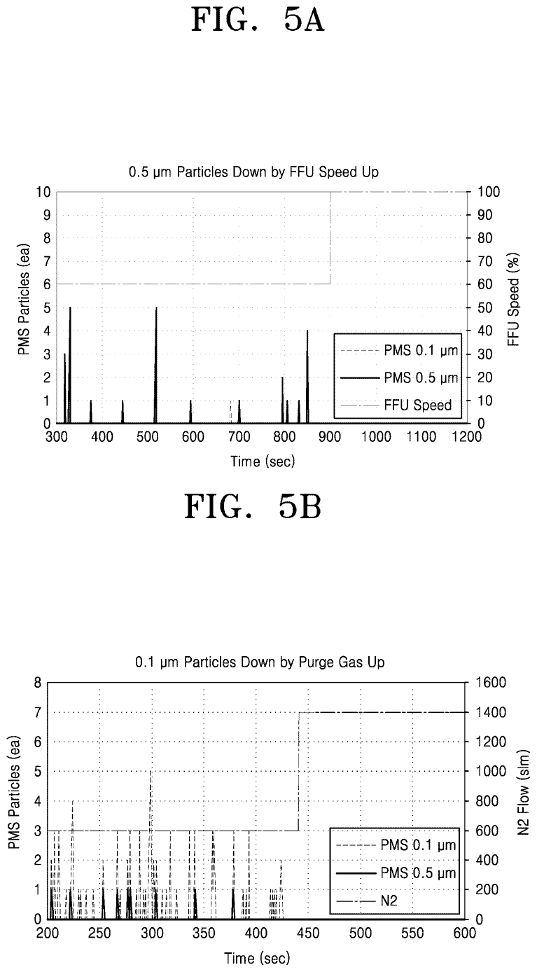

FIGS. 5a and 5b are graphs illustrating changes in the amount of particles according to the operations of the external air inlet 70 and gas control device 80 of the substrate-processing apparatus according to an embodiment of the present disclosure.

Specifically, FIG. 5a is a graph illustrating the sizes of particles detected by the particle-measuring sensor 40 over time, and particles detected after the fan filter unit is operated. Here, the size preset by the particle size determination part 52 is 0.5 μm, and the standard flow rate control of the fan filter unit is 60%.

As shown in FIGS. 5a, 4 to 5 particles having a size of 0.5 μm or more were detected at 300 sec, 500 sec, 800 sec, and 850 sec. Next, the speed of the fan filter unit was operated at 100% at 900 sec, so that particles were not detected by the particle-measuring sensor 40. That is, particles floating in the loading area A can be exhausted to the outside through the maximum operation of the fan filter unit.

In addition, FIG. 5b is a graph illustrating the size of particles detected by the particle-measuring sensor 40 over time and particles detected after the gas control device 80 is operated. Here, the size preset by the particle size determination part 52 is 0.1 μm, and the standard flow rate control of the gas control device 80 is 600 slm.

As shown in FIGS. 5b, 3 to 5 particles having a size of 0.1 μm were detected at 250 sec to 430 sec. Next, the nitrogen gas flow rate of the gas control device 80 was sprayed at 1400 slm at 450 sec, so that no particles were detected by the particle-measuring sensor 40. That is, by increasing the flow rate of the inert gas of the gas control device 80, the formation of particles by chemical reaction may be suppressed, and particles floating in the loading area A may be exhausted to the outside.

The substrate-processing apparatus and substrate-processing method according to an embodiment of the present disclosure may monitor particles inside the loading area by size in real-time, and when particles are generated, the particles may be reduced through a suppression control algorithm. In addition, depending on particles due to physical detachment and particles due to chemical reaction, the external air inlet 70 or the gas control device 80 may be selectively controlled to control differently depending on the cause of occurrence, thereby preventing the occurrence of additional particles and, accordingly, improving the processing quality of the substrate.

Although the present disclosure has been described with reference to embodiments shown in the drawings, the embodiments are provided as only exemplary examples, and those skilled in the art will understand that various modifications and equivalent other embodiments are possible therefrom. Therefore, the true technical protection scope of the present disclosure should be determined by the technical spirit of the appended claims.

1. A substrate-processing apparatus, comprising:
a reaction tube which has an opening at a bottom thereof and in which substrate processing is performed;
a boat which is introduced into and taken out from the reaction tube through a boat-lifting unit and on which multiple substrates are seated in a vertical direction;
a substrate-loading part which is placed under the reaction tube and in which a loading area is formed, the multiple substrates being loaded and unloaded into the boat in the loading area through a substrate transfer robot;
an external air inlet which is formed on one side of the substrate-loading part, is connected to the loading area such that external air is introduced into the loading area, and controls an amount of the introduced external air;
a gas control device which controls an injection amount of inert gas supplied into the loading area;
a particle-measuring sensor which measures particle information of the loading area; and
a controller which controls one or more of the external air inlet and the gas control device according to the particle information received from the particle-measuring sensor to reduce particles in the loading area.

2. The substrate-processing apparatus according to claim 1, wherein the controller comprises:
a particle amount determination part which compares an amount of particles measured by the particle-measuring sensor with a preset reference value; and
a particle size determination part that determines sizes of particles measured by the particle-measuring sensor when the particles are measured to be equal to or larger than the reference value.

3. The substrate-processing apparatus according to claim 1, wherein the controller controls an intensity of the external air inlet to increase an amount of external air flowing into the loading area when particles larger than a preset size are measured to be equal to or larger than the reference value by the particle-measuring sensor.

4. The substrate-processing apparatus according to claim 1, wherein the controller controls the gas control device to increase an injection amount of inert gas when particles smaller than a preset size are measured to be equal to or larger than the reference value by the particle-measuring sensor.

5. The substrate-processing apparatus according to claim 1, wherein the controller respectively operates the external air inlet and the gas control device at predetermined time intervals such that an amount of external air flowing into the loading area and an injection amount of inert gas are alternately increased when particles larger than a preset size are measured to be equal to or larger than the reference value and particles smaller than the preset size are measured to be equal to or larger than the reference value by the particle-measuring sensor.

6. The substrate-processing apparatus according to claim 1, wherein the external air inlet comprises a fan filter unit that is formed on one side of the loading area and controls an amount of external air flowing from the external air inlet.

7. A substrate-processing method, comprising:
a process processing step in which a boat where multiple substrates are seated in a vertical direction through a boat-lifting unit is introduced into or taken out from an opening formed at a bottom of a reaction tube, in which substrate processing is performed, to process the multiple substrates;
a particle measurement step of measuring particle information of a loading area in a substrate-loading part placed under the reaction tube before or after the process processing step, the multiple substrates being loaded and unloaded into the boat in the loading area; and
a control step of controlling one or more of an external air inlet for controlling an amount of external air flowing into the loading area; and a gas control device for controlling an injection amount of inert gas supplied into the loading area, so as to reduce particles in the loading area according to the particle information measured in the particle measurement step.

8. The substrate-processing method according to claim 7, wherein the control step comprises:
a particle amount determination step of comparing an amount of particles measured in the particle measurement step with a preset reference value; and
a particle size determination step of determining a size of particles measured in the particle measurement step when the particles are measured to be equal to or larger than the reference value.

9. The substrate-processing method according to claim 7, wherein the control step comprises:
a fan filter unit a control step of controlling an intensity of the external air inlet to increase an amount of external air flowing into the loading area when particles larger than a preset size are measured to be equal to or larger than a reference value in the particle measurement step.

10. The substrate-processing method according to claim 7, wherein the control step comprises:
a gas supply control step of controlling the gas control device to increase an injection amount of inert gas when particles smaller than a preset size are measured to be equal to or larger than a reference value in the particle measurement step.
